(19) United States
(12) Patent Application Publication
(10) Pub. No.: US 2024/0033841 A1
(43) Pub. Date: Feb. 1, 2024

(54) METHOD FOR DETERMINING THE WAVE HEIGHT OF A SOLDERING WAVE, DEVICE FOR DETERMINING THE WAVE HEIGHT OF A SOLDERING WAVE AND WAVE SOLDERING SYSTEM

(71) Applicant: ERSA GmbH, Wertheim (DE)

(72) Inventors: Florian Völker, Remlingen (DE); Stefan Völker, Hafenlohr (DE)

(21) Appl. No.: 18/223,680

(22) Filed: Jul. 19, 2023

(30) Foreign Application Priority Data
Jul. 27, 2022 (DE) 10 2022 118 883.3

(51) Int. Cl. B23K 3/08; B23K 3/06

(52) U.S. Cl. CPC B23K 3/08; B23K 3/0638; B23K 3/087

(57) ABSTRACT

A device (16) and method for determining the wave height (H) of a solder wave (42) formed from liquid solder (41) and conveyed by a solder nozzle assembly (12) is provided. The device includes a resiliently flexible film body (18) for floating placement on the solder wave (42) and a measuring unit (38) for determining the position of the surface of the film body (18) floating on the solder wave relative to a reference point (39). The device has an evaluation unit (44) for determining the wave height (H) depending on the position of the film body (18). A wave soldering machine is also provided.

### FIELD

This disclosure relates to a method for determining the wave height of a solder wave, a device for determining the wave height of a solder wave, and a wave soldering machine.

### BACKGROUND

During manufacture of mounted printed circuit boards, it is known to connect the components arranged on the printed circuit board to the printed circuit board by means of wave soldering.

In wave soldering machines, a comparatively wide solder wave made of liquid solder is provided, the components to be soldered being moved through the stationary solder wave.

In installations for selective wave soldering, a plurality of soldering nozzles are often arranged for example on a nozzle plate such that the outlet openings of the soldering nozzles point substantially vertically upward when in the soldering position. The cross section of each soldering nozzle is in this case shaped specifically for the soldering region, and each soldering nozzle is associated with a specific region of the printed circuit board that is to be soldered. In order to solder, the soldering nozzle or the nozzle plate comprising the soldering nozzles arranged thereon is pulled up to the printed circuit board to be soldered from below. At the same time, liquid solder flows through the interior of the soldering nozzle from below, emerges in a wave-like manner at the nozzle opening which is at the top when in the soldering position, and wets the solder joints of the printed circuit board positioned there such that the desired solder connection is produced between the component to be soldered—or between the wire projection of the component—and the associated region of the printed circuit board conductor path.

Precise control of all of the process parameters, such as temperatures, solder flow rates, distances, feed rates, etc., is of great importance during wave soldering, or during multi-wave soldering using multiple soldering nozzles, in order to obtain high-quality solder joints with high reproducibility. A central requirement for wave soldering is that the height of the wave consisting of liquid solder can be exactly determined and readjusted.

A wave soldering machine having a wave height test system is known from DE 10 2015 212 960 A1. There, a needle is used in a reference nozzle, the free end of which defines a test point of a test height. When the free end of the needle comes into contact with the liquid solder, an electrical signal is generated. This device can only determine whether the test height is reached. It is not possible to determine to what degree the test height is not reached or is exceeded. A readjustment of the pump drive by a constant test height therefore cannot be achieved or can be achieved only to a limited extent.

Another wave soldering machine is known from DE 10 2013 225 887 A1, in which a measuring element in the form of a measuring strip is provided, at which the height of the soldering wave is ultimately read off.

DE 44 18 732 A1 discloses a method and a device for measuring and/or controlling the height of a solder wave. In this case, the height of the wave is measured in a branch, the wave height being determined in the branch via a sensor.

CN 2 025 91 786 discloses placing a floating body on a wave of liquid solder in order to determine its height at a reference point. In this case, the floating body can be connected via a connection arrangement to a piston which is movable in a closed space, it being possible for the changing pressure in the space to be measured via pressure sensors present in the space in the event of a volume change of the space.

It is known from DE 10 2018 105 900 A1 to determine the height of the solder wave via the buoyancy force of a floating body.

Further systems for determining the height of surfaces of liquids are known from CN 1 02 967 342 A, JP H07-270 216 A, DE 102 43 769 B4, and DE 197 04 764 A1.

### SUMMARY

The object of this disclosure is to provide a method for determining the wave height of a solder wave, a device for determining the wave height of a solder wave, and a wave soldering machine for operating such a method, by means of which the wave height can be measured in a simple manner and in a functionally reliable manner.

This object is achieved by means of a method having the features of claim 1. The method is characterized in particular by the following steps:
placing a resiliently flexible film body onto the solder wave such that the film body floats on the solder wave,
determining the position of the surface of the film body floating on the solder wave with respect to a reference point, and
determining the wave height depending on the position of the film body.

By placing the resiliently flexible film body onto the solder wave, said body floats on or along the surface of the solder wave. As a result of the resilient design, the film body can be adapted at least in portions to the surface of the solder wave or can come to rest on it in a floating manner. In this case, the provision of the film body forms a reference surface which can be detected in a simple manner. The surface of the film body can be used as a reference surface and measuring plane even when the liquid solder flows comparatively quickly and when vortices or eddies form in the liquid solder. Due to the fact that the film body preferably has a very low thickness, in particular in the range from 0.1 mm to 0.3 mm and preferably in the region of 0.2 mm, it can be ensured that it does indeed float on the liquid solder. Due to the fact that the film body has a certain width, which is preferably in the range from 1 cm to 10 cm, and more preferably in the range from 2 cm to 5 cm, the film body ultimately forms a mean value of the height of the region of the solder wave which it covers.

By determining the position of the surface of the film body floating on the solder wave with respect to a reference point, the wave height of the solder wave can ultimately be determined. The higher the wave height, the greater or smaller the distance is from the reference point towards the surface of the film body.

It has been found to be advantageous if, in order to determine the position of the surface of the film body, a reference distance between the reference point and a measuring unit is first measured. The distance of the reference point from the measuring unit is therefore first measured, in a reference measurement. In order to determine the wave height, a wave distance between the surface of the film body floating on the solder wave and the measuring unit is then measured. The distance of the surface of the film body floating on the solder wave and deflected by the solder wave from the measuring unit is thus measured. The wave height can then be determined from the difference between the reference distance and the wave distance, optionally taking into account further magnitudes or geometries.

In this case, it is conceivable that the surface of the film body resting on an edge of the solder nozzle assembly is used as the reference point. In particular when no liquid solder emerges from the solder nozzle assembly, the film body can be placed on the solder nozzle assembly or its tear-off edge. The reference point is then formed by the surface of the film body. The reference distance is then the distance between the surface of the film body resting on the edge, and the measuring unit. If liquid solder flows through the solder nozzle assembly, the film body changes its relative position with respect to the edge of the solder nozzle assembly, and floats on the liquid solder. The wave distance from the surface of the film body deflected by the wave, to the measuring unit, is reduced relative to the reference distance. In this case, the wave height can be deduced from the difference between the reference distance and the wave distance.

Furthermore, it is conceivable that the surface of the film body resting on the edge of the solder nozzle assembly is not used as reference point, but rather that the edge of the solder nozzle assembly is used directly. The reference point is then independent of the film body. Furthermore, it is conceivable that other locations are used as reference points.

The reference distance and the wave distance can be measured in particular by means of a radar measuring unit, a laser measuring unit, an optical, inductive or capacitive measuring unit and/or an ultrasound measuring unit.

The object mentioned at the outset is also achieved by a device for determining the wave height of a solder wave, which is formed of liquid solder and conveyed by a solder nozzle assembly, the device comprising a resiliently flexible film body for floating placement on the solder wave, a measuring unit for determining the position of the surface of the film body floating on the solder wave with respect to a reference point, and an evaluation unit for determining the wave height depending on the position of the film body. Depending on the wave height, the film body consequently assumes a different position in space. The measuring unit can detect this position with respect to the reference point. The evaluation unit ultimately determines the wave height from the detected position.

It is conceivable in this case for the measurement unit and the evaluation unit to be designed as a common component, this one component then containing the measurement function and the evaluation function.

It is further advantageous if the measuring unit is configured to measure a reference distance between the reference point and the measuring unit and to measure a wave distance between the surface of the film body floating on the solder wave and the measuring unit. The wave distance is therefore the distance between the surface of the solder wave or the upper side of the film body floating on the solder wave, and the measuring unit. In the case of known geometries, the wave height can then be deduced from these two distances.

For positionally accurate arrangement of the film body and/or the measuring unit, it is advantageous if the film body and/or the measuring unit are arranged on a holding device. In this case, the holding device can position both the film body and the measuring unit relative to one another in space. The holding device can also be designed as a holding frame which encloses the measuring unit and/or the film body at least in portions.

Furthermore, it is advantageous if the holding device has a displacement mechanism, by means of which the film body can be displaced between a measuring location, in which it rests in a floating manner on the solder wave, and a parked location, in which it is located in a parked position. While the wave height can be determined in the measuring position, soldering of the components can take place in the parked location, without the holding device being in the way, in a disruptive manner, for this.

In this case, the displacement mechanism can be designed as a lifting mechanism for displacing the film body in the vertical direction for retracting and extending. In the retracted position, the film body is then in particular in the parked position, and in the extended position it is in the measurement position.

Furthermore, it is conceivable that the displacement mechanism is designed as a pivot mechanism for pivoting the film body about a pivot axis into the measurement location, and for pivoting out into the parked position. In the event that the wave height is to be measured, the film body is then pivoted into the measuring location.

Furthermore, it is conceivable that an adapter element is provided which encloses an acute angle with a vertical plane, the film body being arranged on the adapter element. By means of the adapter element, it is achieved that the film body assumes a location which corresponds at least largely to the surface of the wave, when it does not float on the wave. Consequently, the film body can thus be aligned in parallel with the wave surface and thus be moved towards the solder wave.

It has been found to be advantageous if the film body is designed as a metal sheet. However, it is also conceivable to provide a plastics material for the film body.

Furthermore, it is advantageous if the film body has a surface which is easily detectable by the measuring unit. For this purpose, the film body can provide, for example, a suitable coating or a suitable color.

Furthermore, it is conceivable that the film body has a rectangular shape having two longitudinal sides and two narrow sides in plan view. The shape is in particular such that the film body can come to rest as far as possible in a freely floating manner on the solder wave.

It is further advantageous if the film body has a base surface and edge regions having free edges, the edge regions forming an angle relative to the base surface in the range of 30° to 150°, and in particular in the range of 70 ° to 110°, and more particularly in the region of 90°. The edge regions are preferably connected to one another in a fluid-tight manner and are designed in such a way that flooding of the film body is prevented, so that it is ensured that the film body floats on the surface of the solder wave.

The object mentioned at the outset is also achieved by a wave soldering machine having a solder nozzle assembly, having a pump for conveying liquid solder through the solder nozzle assembly to form a solder wave, and having a device according to the disclosure for determining the wave height of the solder wave.

In this case, it is advantageous if the wave soldering machine has a displacement unit that can be moved along an x-direction and/or y-direction, the device for determining the wave height being arranged on the displacement unit.

Furthermore, it is conceivable that not only one device but multiple devices are provided on such a displacement unit. This has the advantage that the height of the solder wave can be determined at different points in the case of a comparatively wide solder wave. The process reliability can also be increased thereby.

In order to prevent contamination or damage to the measuring unit, it is advantageous if a protective screen is provided between the film body and the measuring unit. The protective screen serves in particular as a splash and heat protection of the measuring unit.

Further details and advantageous embodiments and aspects of this disclosure can be found in the following description by which embodiments and aspects of this disclosure are described and explained in more detail.

### BRIEF DESCRIPTION OF THE DRAWINGS

FIG. 1 shows a wave soldering machine having a device for determining the wave height in a reference state;

FIG. 2 shows the wave soldering machine according to FIG. 1 in a measuring state; and

FIG. 3 shows a film body for a device for determining the wave height with an adapter.

### DETAILED DESCRIPTION

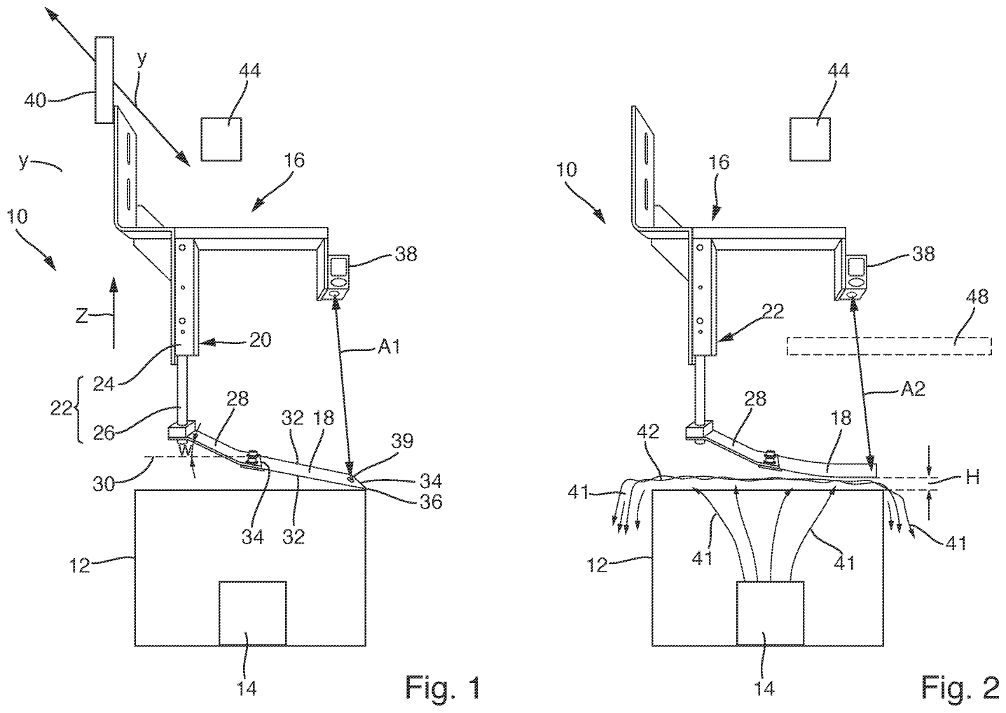

FIG. 1 shows a wave soldering machine 10 which provides a solder nozzle assembly 12 and a pump 14 for pumping liquid solder through the solder nozzle assembly 12. In FIG. 1, no liquid solder is conveyed by the pump 14 through the solder nozzle assembly 12.

FIG. 1 further shows a device 16 for determining the wave height of a solder wave, the device 16 having a resiliently flexible film body 18 which is arranged on a holding device 20. The holding device 20 in turn has a displacement mechanism 22 which is designed as a lifting mechanism for displacing the film body 18 in the direction of a vertically extending z-axis. The displacement mechanism 22 is formed by a base body 24 having actuating elements 26 movable therein in the direction of the z-axis. The actuating elements 26 can thus be retracted and extended in the direction of the z-axis. An adapter element 28, on which the film body 18 is ultimately fastened, is provided at the free ends of the actuating elements 26. The adapter element 28 is arranged in such a way that it encloses an acute angle w with a horizontal 30 so that the film element 18 is ultimately likewise arranged extending obliquely to the horizontal 30.

The film element 18 is in turn designed in particular as a spring steel sheet and has a rectangular basic shape having two longitudinal sides 32 and two narrow sides 34. In this case, one narrow side 34 is fixedly arranged on the adapter element 28. The other narrow side 34 is a free narrow side, which in FIG. 1 rests against a tear-off edge 36 of the solder nozzle assembly 12. The film body 18 has in particular a thickness of 0.1 mm to 0.2 mm. In particular, the wave height H can be detected with a tolerance of/−0.1 mm to 0.25 mm. In this case, the resiliency of the film body 18 is designed in such a way that it is ensured that it is deflected by a solder wave 42 and reliably floats on the latter.

In order to ensure that the free narrow side 34 comes to rest against the tear-off edge 36, the adapter element 28 together with the film body 18 can be moved in the z-direction via the displacement mechanism 22 until the film body 18, or its free narrow side 34, comes to rest against the tear-off edge 36.

The device 16 further has a measuring unit 38 in the form of a laser measuring unit, which measures the distance A₁ between a reference point 39, which lies on the surface of the film body 18 resting on the tear-off edge 36, and the measuring unit 38. Distance A₁ is a reference distance since it is measured without taking into account the solder wave forming during operation of the machine.

The surface of the film body 18 is in particular painted or coated in order to enable precise measurement of the distance A by the measuring unit 38.

The device 16 can be arranged on a displacement unit 40, which is only schematically indicated in FIG. 1, so as to be displaceable in a y-direction extending transversely to the z-direction.

During operation of the wave soldering machine 10, i.e., when printed circuit boards are soldered, the device 16 is in a parked position (not shown).

If the wave height H of a solder wave 42, consisting of liquid solder 41, which is shown in FIG. 2, is by the pump 14 and passes through the solder nozzle assembly 12, is intended to be determined, the device 16 is moved from the parked position (not shown in the figures) into the measuring position shown in FIG. 2. In this case, the device 16 is located in the same position as in FIG. 1. Due to the presence of the solder wave 42 and the placement of the flexible film body 18 on the solder wave 42, the film body 18 floats on the solder wave 42 and thus is deflected upward due to the presence of the solder wave 42.

This results in a wave distance A₂ between the measuring unit 38 and the surface of the film body 18 floating on the solder wave 42.

Thus, if the distance between the measuring unit 38 and the surface of the film body 18 is measured in the measuring location shown in FIG. 2, and this distance A₂ is compared with reference distance A₁, the wave height H can ultimately be determined by means of an evaluation unit 44 indicated schematically in FIGS. 1 and 2. The wave height H can be determined in the embodiment shown in the figures by the difference of the reference distance A₁ and the wave distance A₂: H=A₁−A₂. In this case, the evaluation unit 44 can be integrated into the measuring unit 38.

The measurement of the distances A₁ and A₂ in this case preferably takes place in the region of the surface of the film body 18, the underside of which is located in the liquid solder of the solder wave.

However, according to the disclosure it is conceivable that the reference point 39, as shown in FIG. 1, does not lie on the surface of the joint body, but is formed, for example, by the tear-off edge 36. In this case, geometric conditions such as the thickness of the film body 18 must be taken into account when determining the wave height H.

The wave height H determined by means of the device 16 can in particular be displayed to a user or communicated to a superordinate controller. Depending on the wave height H, signals can then be generated and/or measures can be taken.

In order to protect the measuring unit 38 from heat and solder splashes, a protective screen 48, indicated in FIG. 2, is advantageously provided between the measuring unit 38 and the film body 18.

Even if the distance A₂ between the measuring unit 38 and the surface of the film body 18 is measured at only one point in the figures, it is conceivable that the measurement takes place at multiple points so that a more accurate, possibly averaged, measurement result is achieved.

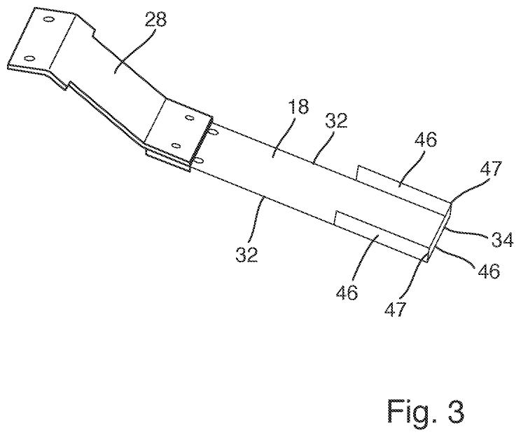

An alternative embodiment of a film body 18 on an adapter element 28 is shown in FIG. 3. In the region of its free narrow side 34 and in the region of the portions of the longitudinal sides 32 facing the narrow side 34, the film body 18 has edge regions 46 which are folded upward perpendicularly to the plane of the film body 18. The folded regions are connected to one another in a water-tight manner, in the corners. This achieves a better floating behavior of the film body 18 on the solder wave 42. Furthermore, liquid solder 41 is prevented from flooding the upper side of the film body 18, which would ultimately falsify the measurement result. Instead of or in addition to the upwardly folded edge regions 46, it is conceivable that further and/or additional elements or means are provided on the upper side of the film body 18, which elements or means prevent the film body from dipping into the solder wave.

What is claimed is:

1. A method for determining the wave height (H) of a solder wave (42), wherein liquid solder (41) is conveyed through a solder nozzle assembly (12) to form the solder wave (42), the method comprising:
placing an elastically flexible film body (18) on the solder wave (42) such that the film body (18) floats on the solder wave (42),
determining the position of the surface of the film body (18) floating on the solder wave relative to a reference point (39), and
determining the wave height (H) depending on the position of the film body (18).

2. The method according to claim 1, wherein, for determining the relative position of the surface of the film body (18), a reference distance (A₁) between the reference point (39) and a measuring unit (38) is measured, and that a wave distance (A₂) between the surface of the film body (18) floating on the solder wave and the measuring unit (38) is measured.

3. The method according to claim 1, wherein the surface of the film body (18) resting on an edge (36) of the solder nozzle assembly (12) is used as the reference point (39).

4. The method according to claim 1, wherein an edge (36) of the solder nozzle assembly (12) is used as the reference point.

5. The method according to claim 2, wherein the distance (A₁, A₂) is measured by a measuring unit (38) in the form of a radar measuring unit, a laser measuring unit, an optical, inductive or capacitive measuring unit, and/or an ultrasound measuring unit.

6. A device (16) for determining the wave height (H) of a solder wave (42) formed from liquid solder (41) and conveyed by a solder nozzle assembly (12),
having a resiliently flexible film body (18) for floating placement on the solder wave (42),
having a measuring unit (38) for determining the position of the surface of the film body (18) floating on the solder wave relative to a reference point (39), and
having an evaluation unit (44) for determining the wave height (H) depending on the position of the film body (18).

7. The device (16) according to claim 6, wherein the measuring unit (38) is designed for measuring a reference distance (A₁) between the reference point (39) and the measuring unit and for measuring a wave distance (A₂) between the surface of the film body (18) floating on the solder wave and the measuring unit (38).

8. The device (16) according to claim 6, wherein the film body (18) and/or the measuring unit (38) are arranged on a holding device (20).

9. The device (16) according to claim 8, wherein the holding device (20) has a displacement mechanism (22) that displaces the film body (18) between a measuring position in which the film body rests in a floating manner on the solder wave (42) and a parked location in which the film body is in a parked position.

10. The device (16) according to claim 9, wherein the displacement mechanism (22) is configured as a lifting mechanism for displacing the film body (18) in the vertical direction for retraction and extension.

11. The device (16) according to claim 9, wherein the displacement mechanism is configured as a pivot mechanism for pivoting the film body (18) about a pivot axis into the measuring position and for pivoting the film body out into the parked position.

12. The device (16) according to claim 6, wherein the holding device (20) has an adapter element (28) which encloses an acute angle (w) with a vertical plane (30) and on which the film body (18) is arranged.

13. The device (16) according to claim 6, wherein the film body (18) is formed by a metal sheet.

14. The device (16) according to claim 6, wherein the film body (18) has a rectangular shape in plan view having two longitudinal sides (32) and two narrow sides (34).

15. The device (16) according to claim 6, wherein the film body (18) has a base surface and edge regions (46) having free edges, wherein the edge regions (46) enclose an angle in the range of 30-150°.

16. A wave soldering machine (10) having a solder nozzle assembly (12), having a pump (14) for conveying liquid solder (41) through the solder nozzle assembly (12) to form a solder wave (42), and having a device (16) according to claim 6.

17. The wave soldering machine (10) according to claim 16, having a displacement unit (40) movable along an x-direction and/or y-direction, wherein the device (16) is arranged on the displacement unit (40).

18. The wave soldering machine (10) according to claim 16, wherein a protective screen (48) is provided between the film body (18) and the measuring unit (38).
